(19) United States
(12) Patent Application Publication
(10) Pub. No.: US 2005/0140439 A1
(43) Pub. Date: Jun. 30, 2005

(54) Predistortion linearizer for power amplifier

(76) Inventors: Chang Hee Hyoung, Daejeon-city (KR); Jung Hwan Hwang, Daejeon-city (KR); Jin Bong Sung, Daejeon-city (KR); Sung Weon Kang, Daejeon-city (KR); Yun Tae Kim, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/990,744

(22) Filed: Nov. 16, 2004

(30) Foreign Application Priority Data
Dec. 26, 2003 (KR) 2003-97819
Jul. 1, 2004 (KR) 2004-51002

(51) Int. Cl. H03F 1/26

(52) U.S. Cl. 330/149

(57) ABSTRACT

There is provided a predistortion linearizer for suppressing the gain and phase distortions in a power amplifier arranged between input and output stages including a transistor which is arranged between the input stage and the power amplifier and has a base-emitter junction diode, and a resistor arranged in series between the transistor and the power amplifier.

### BACKGROUND OF THE INVENTION

This application claims the priority of Korean Patent Application Nos. 2003-97819, filed on Dec. 26, 2003 and 2004-51002, filed on Jul. 1, 2004, in the Korean Intellectual Property Office, the disclosures of which are incorporated herein in their entirety by reference.

1. Field of the Invention

The present invention relates to a high-efficiency micro linear power amplifier for use in mobile and satellite communications, and more particularly, to a predistortion linearizer for compensating for the gain and phase distortions in the power amplifier.

2. Description of Related Art

In general, a power amplifier should be operated around the saturation region in order to improve the efficiency of the power amplifier for use in mobile and satellite communications. However, in doing so, the amplitude and phase distortions in the power amplifier increase as the input power increases. The amplitude and phase distortions produce interference between adjacent channels, causing deterioration in the system performance. One of the methods proposed for compensating for the amplitude and phase distortions is to arrange a predistortion linearizer on the previous stage of the power amplifier.

FIG. 1 is a circuit diagram showing a typical power amplifier. FIG. 2 is a diagram showing input power versus gain characteristics and input power versus phase characteristics in the power amplifier having a predistortion linearizer.

A transistor Q11, a power amplifier, is arranged between an input stage P11 and an output stage P12. The base of the transistor Q11 is connected to the input stage P11, and the collector is connected to the output stage P12. A bias circuit consisting of resistors R11 and R12 is arranged between the input stage P11 and the base of the transistor Q11.

As the input power increases, a rectified current of the base-emitter diode of the transistor Q11 also increases. However, a voltage across the base-emitter diode of the transistor Q11 decreases due to the resistors R11 and R12 constituting the bias circuit. As a result, the gain of an output signal decreases as the input power increases, which is called negative distortion. Meanwhile, as the input power increases, the base-collector junction capacitance of the transistor Q11 varies. As a result, the phase of the output signal increases as the input power increases, which is called positive distortion.

A predistortion linearizer 210 and a power amplifier 220 are sequentially arranged between an input stage P21 and an output stage P22. As shown in graph (b) of FIG. 2, the power amplifier 220 generates an output signal with a reduced gain and an increased phase as the input power increases. On the contrary, as shown in graph (a) of FIG. 2, the predistortion linearizer 210 generates an output signal with an increased gain and a reduced phase as the input power increases. Accordingly, the increased gain and the reduced phase in the predistortion linearizer 210 compensate for the reduced gain and the increased phase in the power amplifier 220, so that an output signal with no gain and phase distortions is generated although the input power increases, as shown in graph (c) of FIG. 2.

FIG. 3 is a circuit diagram showing a conventional example of the predistortion linearizer 210 in FIG. 2.

A capacitor Cp31 and a diode D31, which are connected in parallel to each other, are arranged between an input stage P31 and an output stage P32. The anode of the diode D31 turns toward the input stage P31 and the cathode turns toward the output stage P32. Capacitors C31 and C32 for blocking the flow of a direct current in a circuit are arranged between the diode D31 and the input stage P31, and between the diode D31 and the output stage P32, respectively. Meanwhile, inductors L31 and L32 are components for feeding a direct current, and “Vcc31” denotes a bias voltage terminal.

This predistortion linearizer produces an increased amplitude and a reduced phase due to the non-linearity of an equivalent resistance of the diode D31 when the input power increases, resulting in compensating for the reduced gain and increased phase in the power amplifier. However, there is a disadvantage in which the predistortion linearizer requires an additional bias circuit for driving the diode D31 and thus an additional power consumption occurs.

FIG. 4 is a circuit diagram showing another conventional example of the predistortion linearizer 210 in FIG. 2.

The predistortion linearizer comprises a diode D41, a bias feed resistor R41, and capacitors C41 and C42 for blocking the flow of a direct current, which are connected in parallel between an input stage P41 and an output stage P42. In this predistortion linearizer, when the input power increases, a voltage drop due to the flow of a rectified current in the diode D41 causes a decrease in a voltage Vd applied to the diode D41. The reduced voltage Vd results in an increase in an equivalent resistance of the diode D41, whereby the predistortion linearizer produces an increased amplitude and a reduced phase. However, there is a disadvantage in that the predistortion linearizer also requires an additional bias circuit for driving the diode D41 and thus an additional power consumption occurs.

FIG. 5 is a circuit diagram showing another conventional example of the predistortion linearizer 210 in FIG. 2.

The base and collector of a transistor Q51 used as an amplifier are connected to an input stage P51 and an output stage P52, respectively. The base of the transistor Q51 is connected to the collector of the transistor Q52. The base of the transistor Q52 is connected to a bias voltage terminal Vbb51 through a resistor R52. The base-collector diode of the transistor Q52 and the resistor R52 form a base biasing circuit of the transistor Q51, and simultaneously, constitute a predistortion linearizer. The resistor R51 connected between the base-emitter of the transistor Q52 has no effect on the predistortion linearizer, and is a component for forward-biasing the transistor Q52. There is no current flowing between the base and emitter of the transistor Q52. The capacitor C52 is a component for providing a low impedance when a radio-frequency (RF) signal is applied from the input stage P51.

In this predistortion linearizer, when the input power increases, a rectified current flowing through the base-collector diode of the transistor Q52 increases and a dc voltage across the diode reduces. The reduced base-collector voltage of the transistor Q52 results in a slight increase in the base-emitter voltage of the transistor Q51. The resulting increment of the base-emitter voltage of the transistor Q51 contributes to improving the gain attenuation and phase distortion characteristics of the transistor Q51 due to the increase of the input power.

This predistortion linearizer, unlike the predistortion linearizer in FIGS. 3 and 4, does not require an additional bias circuit for driving the base-collector diode of the transistor Q52. However, there is a disadvantage in which this predistortion linearizer cannot control an increase of a drive current depending on an input power in designing a power amplifier having an operating point around a saturation region, such as a class AB power amplifier, in order to attain high efficiency.

FIG. 6 is a circuit diagram showing another conventional example of the predistortion linearizer 210 in FIG. 2.

The base and collector of a transistor Q61 used as an amplifier are connected to an input stage P61 and an output stage P62, respectively. The base of the transistor Q61 is connected to the emitter of the transistor Q62. The base-emitter diode of the transistor Q62 and a shunt capacitor C61 constitute a predistortion linearizer. The collector of the transistor Q62 is connected to a bias voltage terminal Vref61. Transistors Q63 and Q64 acting as diodes are arranged to supply a constant voltage to the base of the transistor Q62.

The operation of this predistortion linearizer is similar to the predistortion linearizer of FIG. 5 in that the capacitor C61 connected in parallel to the transistor Q62 is used. In other words, the resistance of a resistor 61 and the impedance of two series-connected diodes Q63 and Q64 are higher than the impedance of the capacitor C61 at radio frequencies. As a result, all of the radio frequency signals in the base of the transistor Q62 flow through the capacitor C61, whereby a voltage in the base of the transistor Q62 is held constant. When the input power increases, the base bias voltage drop of the transistor Q61 is compensated due to the voltage drop across the base-emitter diode of the transistor Q62.

However, there is a disadvantage in which this predistortion linearizer cannot control an increase of a drive current depending on an input power in designing a power amplifier having an operating point around a saturation region, such as a class AB power amplifier, in order to attain high efficiency.

### SUMMARY OF THE INVENTION

The present invention provides a predistortion linearizer for a power amplifier that does not require an additional bias circuit for a diode constituting the predistortion linearizer, and simultaneously, can control an increase of a drive current depending on an input power.

According to an aspect of the present invention, there is provided a predistortion linearizer for suppressing the gain and phase distortions in a power amplifier arranged between input and output stages, the predistortion linearizer comprising: a transistor arranged between the input stage and the power amplifier, and including a base-emitter junction diode; and a resistor arranged in series between the transistor and the power amplifier.

The power amplifier may be a bipolar junction transistor (BJT) including a hetero-junction BJT.

In this case, the bipolar junction transistor may be an npn-type bipolar junction transistor where the base is connected to the input stage and the resistor and the collector is connected to the output stage.

A transistor constituting the predistortion linearizer may an npn-type bipolar junction transistor including a hetero-junction BJT.

In this case, the emitter of the npn-type bipolar junction transistor constituting the predistortion linearizer may be connected in series to the resistor.

A bias resistor and a diode may be connected in parallel to the npn-type bipolar junction transistor and the resistor constituting the predistortion linearizer.

In this case, at least two diodes may be connected in series to each other, and each of the diodes may be an npn-type bipolar junction transistor including a hetero-junction BJT where the base and the collector are connected to each other.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram showing a typical power amplifier;

FIG. 2 is a diagram showing input power versus gain characteristics and input power versus phase characteristics in the power amplifier having a predistortion linearizer;

FIG. 3 is a circuit diagram showing a conventional example of the predistortion linearizer in FIG. 2;

FIG. 4 is a circuit diagram showing another conventional example of the predistortion linearizer in FIG. 2;

FIG. 5 is a circuit diagram showing another conventional example of the predistortion linearizer in FIG. 2;

FIG. 6 is a circuit diagram showing another conventional example of the predistortion linearizer in FIG. 2;

FIG. 7 is a circuit diagram showing a predistortion linearizer according to the present invention;

FIG. 8 is a graph showing input power versus power-added efficiency characteristics in a power amplifier having a predistortion linearizer according to the present invention; and

FIG. 9 is a graph showing input power versus collector current characteristics in a power amplifier having a predistortion linearizer according to the present invention.

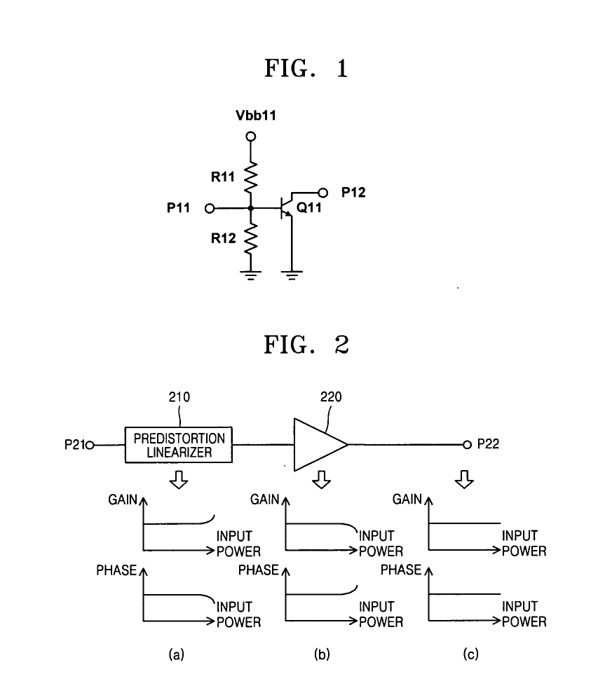

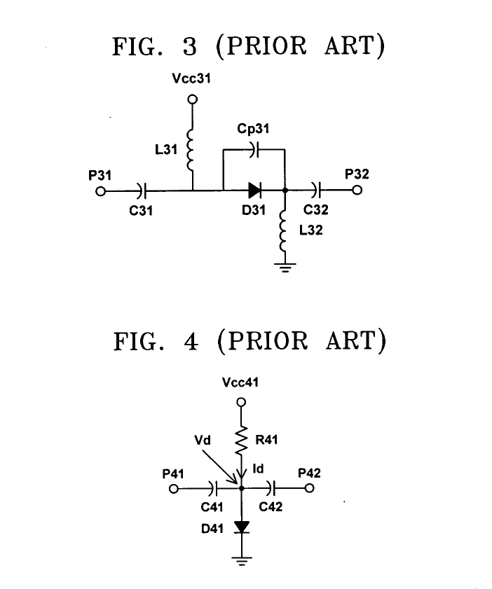

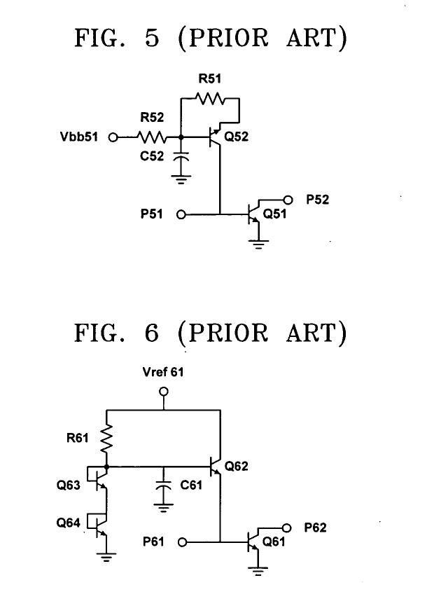

### DETAILED DESCRIPTION OF THE INVENTION

Exemplary embodiments according to the present invention will now be described in detail with reference to the accompanying drawings. The same reference numerals in the drawings denote the same components.

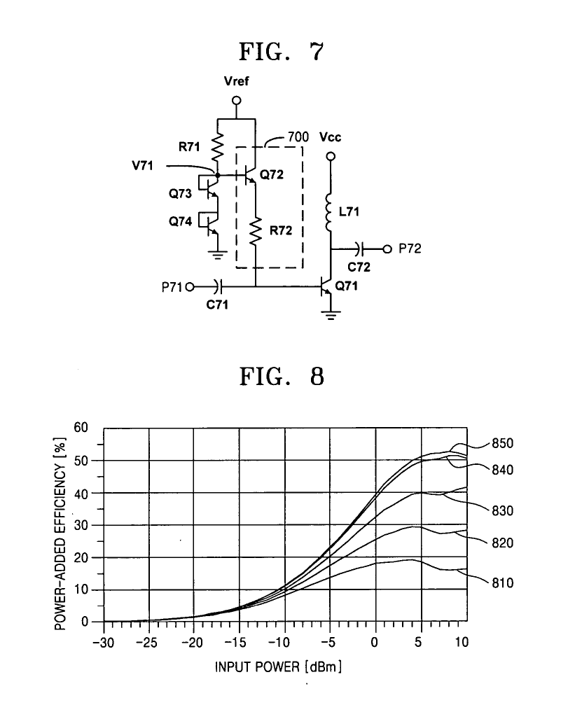

FIG. 7 is a circuit diagram showing a predistortion linearizer according to the present invention.

The base and collector of a transistor Q71 used as a power amplifier are connected to an input stage P71 and an output stage P72, respectively. A capacitor C71 is arranged between the base of the transistor Q71 and the input stage P71. A capacitor C72 is arranged between the collector of the transistor Q71 and the output stage P72. The capacitors C71 and C72 are components for blocking the flow of a direct current. A voltage Vcc is applied to the collector of the transistor Q71 through an inductor L71. A transistor Q72 and a resistor R72 constituting a predistortion linearizer 700 are connected to the base of the transistor Q71. The base of the transistor Q71 is connected to the emitter of the transistor Q72 through the resistor R72. In the present embodiment, the transistors Q71 and Q72 are npn-type bipolar junction transistors including a hetero-junction BJT.

A reference voltage Vref is applied to the collector of the transistor Q72. The series-connected resistor R71 and transistors Q73 and Q74 are connected in parallel to the transistor Q72 and the resistor R72. The transistors Q73 and Q74 constitute a bias circuit and are all npn-type bipolar junction transistors. The transistors Q73 and Q74 act as diodes where the collector and the base are connected to each other. The reference voltage Vref is applied to the resistor R71 and the transistors Q73 and Q74.

The operation of this predistortion linearizer 700 is as follows.

A voltage V71 on the base of the transistor Q72 is held constant by the transistors Q73 and Q74. At this time, when the input power increases, the base-emitter voltage of the transistor Q72 also decreases. The decreased base-emitter voltage of the transistor Q72 prevents the decrease of the base-emitter voltage of the transistor Q71 used as a power amplifier, which increases a 1 dB gain compression point where the gain starts to be distorted due to the reduced base-emitter voltage of the transistor Q71, resulting in increasing the linearity of the power amplifier. Here, the resistor R72 acts to control a rectified current which increases as the input power increases. In other words, when an operating point varies in accordance with the increase of the rectified current, the variation of an increased current can be adjusted by use of an appropriate resistance value of a resistor, resulting in improving the efficiency of the power amplifier.

FIG. 8 is a graph showing input power versus power-added efficiency characteristics in a power amplifier having a predistortion linearizer according to the present invention.

As the input power increases, the power-added efficiency (PAE) also increases. The increment depends on a resistance value of the resistor R72. More specifically, a line 810 denotes a case where the resistor R72 has a resistance value of 40Ω, a line 820 denotes a case where the resistor R72 has 90Ω, a line 830 denotes a case where the resistor R72 has 140Ω, a line 840 denotes a case where the resistor R72 has 190Ω, and a line 850 denotes a case where the resistor R72 has 200Ω. As shown in the graph, it can be seen that the PAE becomes high as the resistance value of the resistor R72 increases. For instance, the PAE increases approximately 34.8% in the case where the resistor R72 has a resistance value of 200Ω (see the line 850) compared to the case where the resistor R72 has 40Ω (see the line 810).

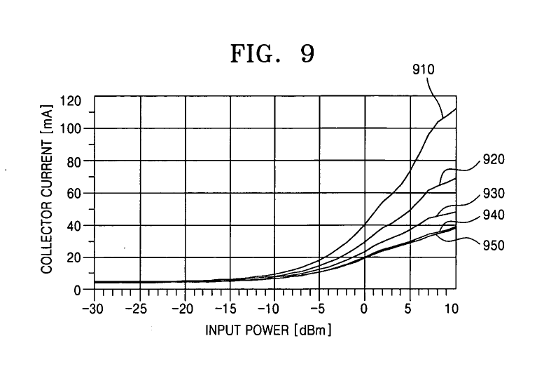

FIG. 9 is a graph showing input power versus collector current characteristics in a power amplifier having a predistortion linearizer according to the present invention.

As the input power increases, the collector current of the transistor Q71 also increases. The increment of the collector current of the transistor Q71 depends on a resistance value of the resistor R72. More specifically, a line 910 denotes a case where the resistor R72 has a resistance value of 40Ω, a line 920 denotes a case where the resistor R72 has 90Ω, a line 930 denotes a case where the resistor R72 has 140Ω, a line 940 denotes a case where the resistor R72 has 190Ω, and a line 950 denotes a case where the resistor R72 has 200Ω. As shown in the graph, the more the resistance value of the resistor R72 increases, the less the collector current of the transistor Q71 increases when the input power increases.

As a result, it is possible to increase the PAE while the output power is held constant, since the variation of an increased current due to the increase of the rectified current can be adjusted by use of the resistor R71.

According to the predistortion linearizer for the power amplifier of the present invention, it is possible to reduce the gain attenuation and the phase distortion in the power amplifier and thus increase the linearity of an component by connecting the emitter of a transistor having a base-emitter diode with the base of a transistor used as a power amplifier and inserting a series resistor therebetween for constituting a predistortion linearizer. In addition, it is possible to increase the PAE while an output power is held constant by use of the series resistor.

While the present invention has been described with reference to exemplary embodiments thereof, it will be understood by those skilled in the art that various changes in form and details may be made therein without departing from the scope of the present invention as defined by the following claims.

1. A predistortion linearizer for suppressing the gain and phase distortions in a power amplifier arranged between input and output stages, the prediction linearizer comprising:
a transistor arranged between the input stage and the power amplifier, and including a base-emitter junction diode; and
a resistor arranged in series between the transistor and the power amplifier.

2. The predistortion linearizer according to claim 1, wherein the power amplifier is a bipolar junction transistor.

3. The predistortion linearizer according to claim 2, wherein the bipolar junction transistor is an npn-type bipolar junction transistor where the base is connected to the input stage and the resistor and the collector is connected to the output stage.

4. The predistortion linearizer according to claim 1, wherein the transistor is an npn-type bipolar junction transistor.

5. The predistortion linearizer according to claim 4, wherein the emitter of the npn-type bipolar junction transistor is connected in series to the resistor.

6. The predistortion linearizer according to claim 4, wherein a bias resistor and a diode are connected in parallel to the npn-type bipolar junction transistor and the resistor.

7. The predistortion linearizer according to claim 6, wherein at least two diodes are connected in series to each other, and each of the diodes is an npn-type bipolar junction transistor where the base and the collector are connected to each other.
